(19) United States
(12) Patent Application Publication
(10) Pub. No.: US 2026/0314243 A1
(43) Pub. Date: Oct. 8, 2026

(54) PROTECTION FILM AND ELECTRONIC DEVICE INCLUDING THE SAME

(71) Applicant: Samsung Display Co., Ltd., Yongin-Si (KR)

(72) Inventor: Jonghwan CHO, Yongin-si (KR)

(21) Appl. No.: 19/410,342

(22) Filed: Dec. 5, 2025

(30) Foreign Application Priority Data
Mar. 25, 2025 (KR) 10-2025-0038346

(51) Int. Cl. H10K 59/80

(52) U.S. Cl. CPC H10K 59/8791; H10K 59/873

(57) ABSTRACT

A protection film and an electronic device including the same are disclosed. The protection film may include a hard coating layer having a high refractive index and an anti-reflection layer disposed on the hard coating layer. In this case, an optical reflectance of a display portion of the electronic device may be reduced, and durability of a folding portion of the electronic device may be increased.

### CROSS-REFERENCE TO RELATED APPLICATIONS

This U.S. non-provisional patent application claims priority under 35 U.S.C. § 119 to Korean Patent Application No. 10-2025-0038346, filed on Mar. 25, 2025, in the Korean Intellectual Property Office, the entire contents of which are hereby incorporated by reference.

### BACKGROUND OF THE INVENTION

The present disclosure relates to a protection film and an electronic device including the same, and in particular, to a protection film including a hard coating layer and an anti-reflection layer and an electronic device including the same.

Various electronic devices are used to provide image information to users, and recently, electronic devices with foldable display modules have been developed.

For the electronic device including the foldable display module, the repetition of the folding operation may degrade the durability of the folding region. Thus, to prevent the degradation of the folding region, a study is being conducted to add protection films with various functions on the display module.

### SUMMARY

An embodiment of the inventive concept provides an electronic device including a protection film, which is configured to improve durability of a folding region.

An embodiment of the inventive concept provides a highly durable electronic device including a hard coating layer, which has a high refractive index and is used to reduce a thickness of an anti-reflection layer.

According to an embodiment of the inventive concept, a protection film may include a base portion, a hard coating layer disposed on the base portion, and an anti-reflection layer disposed on the hard coating layer. The hard coating layer may include silsesquioxane and a titanium chelate oligomer or may include silsesquioxane and an acrylic-based copolymer. The anti-reflection layer may include a first anti-reflection portion, which is disposed adjacent to the hard coating layer to have a first refractive index lower than a refractive index of the hard coating layer.

In an embodiment, the anti-reflection layer may have a single-layered structure having only the first anti-reflection portion or a stacking structure having two or three layers, in addition to the first anti-reflection portion.

In an embodiment, the refractive index of the hard coating layer may range 1.6 from 2.0 at a wavelength of 550 nm.

In an embodiment, the hard coating layer may have the refractive index ranging from 1.6 to 1.75 and include the silsesquioxane and the titanium chelate oligomer, and may have the refractive index ranging from 1.65 to 1.9 and include the silsesquioxane and the acrylic-based copolymer.

In an embodiment, the first refractive index may range from 1.35 to 1.5 at a wavelength of 550 nm.

In an embodiment, the titanium chelate oligomer may be titanium alkoxide oligomer (Ti(ORₐ)₄]ₙ₁), titanium β-diketone oligomer ([Ti(R_{b}COCH₂COR)₄]ₙ₂), or titanium carboxylate oligomer ([Ti(OOCR_{d})₄]ₙ₃), where each of Rₐ, R_{b}, R_{c}, and R_{d} is independently hydrogen, deuterium, a substituted or unsubstituted C₁-C₂₀ alkyl group, a substituted or unsubstituted C₆-C₃₀ aryl group, or a substituted or unsubstituted C₂-C₃₀ heteroaryl group, and each of n1 to n3 is independently an integer greater than or equal to 4 and less than or equal to 8.

In an embodiment, the hard coating layer may include the silsesquioxane and the titanium chelate oligomer and may be directly disposed below the anti-reflection layer.

In an embodiment, the hard coating layer including the silsesquioxane and the titanium chelate oligomer may include a lower layer, which is disposed adjacent to the base portion and includes the silsesquioxane, and an upper layer, which is disposed adjacent to the anti-reflection layer and includes the titanium chelate oligomer.

In an embodiment, a weight ratio between the silsesquioxane and the acrylic-based copolymer may range from 5:95 to 20:80.

In an embodiment, the acrylic-based copolymer may be a copolymer of TIPA (2,4,6-Triiodophenyl acrylate) and HEA (2-hydroxyethyl acrylate) or a copolymer of TIPA and EEA (2-(2-ethoxyethoxy)ethyl acrylate).

In an embodiment, in the acrylic-based copolymer, a weight ratio between TIPA and HEA or a weight ratio between TIPA and EEA may range from 97:3 to 75:25.

In an embodiment, a weight-average molecular weight of the acrylic-based copolymer may range from 10,000 to 30,000.

In an embodiment, a thickness of the anti-reflection layer may range from 80 nm to 350 nm.

In an embodiment, the anti-reflection layer may include at least one of Si₉Al₂O₁₀, SiO₂, Ti₁₄Nb₃O₃₅, and AlF₃.

In an embodiment, the anti-reflection layer may further include a second anti-reflection portion directly disposed on the first anti-reflection portion, and a thickness of the second anti-reflection portion may range from 75 nm to 95 nm.

In an embodiment, the anti-reflection layer may further include a second anti-reflection portion, which is disposed on the first anti-reflection portion and has a second refractive index higher than the first refractive index, and a third anti-reflection portion, which is disposed on the second anti-reflection portion and has a third refractive index lower than the second refractive index.

In an embodiment, the second refractive index may be higher than the refractive index of the hard coating layer.

In an embodiment, the protection film may have a reflectance of 1% or lower, at a wavelength of 550 nm.

According to an embodiment of the inventive concept, an electronic device may include a display module, a window module disposed on the display module, and a protection film disposed on the window module. The protection film may include abase portion disposed on the window module, a hard coating layer disposed on the base portion, the hard coating layer containing silsesquioxane and a titanium chelate oligomer or containing silsesquioxane and an acrylic-based copolymer, and an anti-reflection layer disposed on the hard coating layer, the anti-reflection layer including a first anti-reflection portion, which is disposed adjacent to the hard coating layer to have a first refractive index lower than a refractive index of the hard coating layer.

In an embodiment, the anti-reflection layer may have a single-layered structure only including the first anti-reflection portion or may have a double- to triple-layered structure including the first anti-reflection portion.

In an embodiment, the refractive index of the hard coating layer may range from 1.6 to 2.0 at a wavelength of 550 nm.

In an embodiment, the electronic device may further include at least one of a processor, a memory, and a power module.

In an embodiment, the electronic device may be a television, a monitor, an external advertising display, a personal computer, a laptop computer, a personal digital terminal, an in-vehicle navigation device, a game console, a smart phone, a tablet, a smartwatch, or a camera.

According to an embodiment of the inventive concept, an electronic device may include a display module including a folding region, a first non-folding region, and a second non-folding region, which are spaced apart from each other with the folding region interposed therebetween, a window module disposed on the display module, and a protection film disposed on the window module. The protection film may include a base portion adjacent to the window module, a hard coating layer disposed on the base portion, the hard coating layer containing silsesquioxane and a titanium chelate oligomer or containing silsesquioxane and an acrylic-based copolymer, and an anti-reflection layer disposed on the hard coating layer. The anti-reflection layer may include a first anti-reflection portion, which is disposed adjacent to the hard coating layer to have a first refractive index lower than a refractive index of the hard coating layer.

In an embodiment, the folding region may have a curvature radius that is greater than or equal to 1.4 R and is smaller than 2.0 R.

In an embodiment, the anti-reflection layer may have a thickness ranging from 80 nm to 350 nm.

In an embodiment, the anti-reflection layer may further include a second anti-reflection portion directly disposed on the first anti-reflection portion, and the second anti-reflection portion may have a thickness ranging from 75 nm to 95 nm.

### BRIEF DESCRIPTION OF THE DRAWINGS

FIG. 1A is a block diagram illustrating an electronic device according to an embodiment.

FIG. 1B is a schematic diagram illustrating electronic devices according to various embodiments.

FIG. 2A is a perspective view illustrating an unfolded state of an electronic device of an embodiment.

FIG. 2B is a perspective view illustrating an in-folding operation of the electronic device according to the embodiment of FIG. 2A.

FIG. 2C is a perspective view illustrating an out-folding operation of the electronic device according to the embodiment of FIG. 2A.

FIG. 3A is a perspective view illustrating an unfolded state of an electronic device of an embodiment.

FIG. 3B is a perspective view illustrating an in-folding operation of the electronic device according to the embodiment of FIG. 3A.

FIG. 3C is a perspective view illustrating an out-folding operation of the electronic device according to the embodiment of FIG. 3A.

FIG. 4 is an exploded perspective view of an electronic device according to an embodiment.

FIG. 5 is a sectional view illustrating the electronic device according to the embodiment of FIG. 4.

FIG. 6 is a sectional view illustrating a protection film according to an embodiment.

FIG. 7 is a sectional view illustrating a protection film according to an embodiment.

FIG. 8 is a sectional view illustrating a protection film according to an embodiment.

FIG. 9 is a sectional view illustrating a protection film according to an embodiment.

FIG. 10 is a sectional view illustrating a protection film according to a comparative example.

FIG. 11 is a sectional view illustrating an electronic device according to an embodiment.

FIG. 12 is an enlarged sectional view illustrating a portion of an electronic device according to an embodiment.

FIG. 13 is a graph showing reflectance characteristics of protection films according to embodiments.

FIG. 14 is a graph showing reflectance characteristics of protection films according to embodiments.

FIG. 15 is a graph showing reflectance characteristics of a protection film according to a comparative example.

### DETAILED DESCRIPTION

In the present specification, when a component (or region, layer, portion, and so on) is described as being “on,” “connected to,” or “coupled with” another component, it means that the component may be directly placed on, connected to, or coupled with the other component, or that a third component may be interposed between them.

The same reference numerals refer to the same elements. Also, in the drawings, the thickness, proportions, and dimensions of elements may be exaggerated for the sake of clarity and ease of explanation. The term “and/or” includes any and all combinations of the associated elements.

Terms such as “first” and “second” may be used to describe various components but should not be interpreted as limiting. These terms are used solely to distinguish one component, part, region, layer, or portion from another. For example, without departing from the scope of the inventive concept, a “first” component, part, region, layer, or portion may be referred to as a “second” one, and likewise, a “second” one may be referred to as a “first” one. The singular forms also include the plural forms unless the context clearly indicates otherwise.

Furthermore, terms such as “below,” “under,” “above,” and “over” are used to describe relative positions of elements as illustrated in the drawings. These terms are relative and are used with reference to the orientations shown in the drawings.

The terms “include” or “have” (and variations thereof) are intended to specify the presence of features, numbers, steps, operations, components, parts, or combinations thereof described in the specification, and are not intended to preclude the presence or addition of one or more other features, numbers, steps, operations, components, parts, or combinations thereof.

Unless otherwise defined, all terms used in the present specification (including technical and scientific terms) have the same meaning as commonly understood by one of ordinary skill in the relevant art. Terms defined in commonly used dictionaries should be interpreted in accordance with their meanings in the context of the relevant technology, and should not be interpreted in an overly idealized or formal sense unless explicitly defined herein.

Hereinafter, embodiments according to the inventive concept will be described with reference to the accompanying drawings.

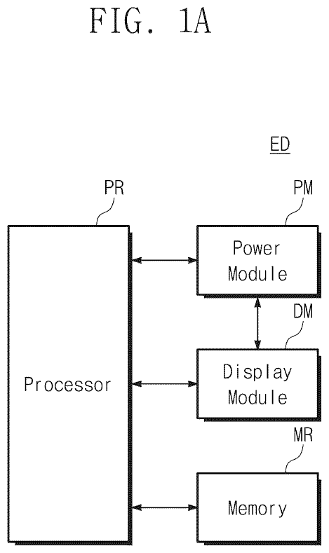

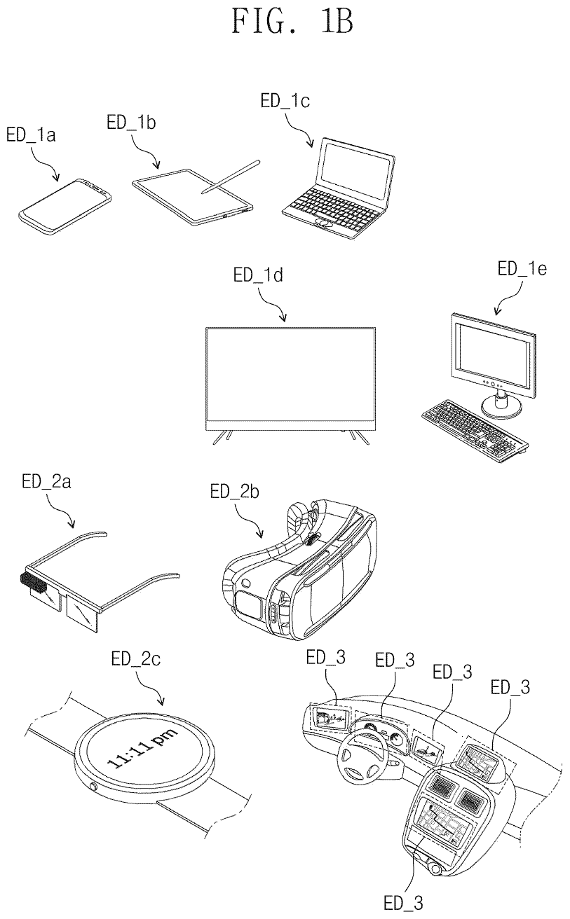

FIGS. 1A to 5 illustrate electronic devices according to embodiments of the inventive concept, and here, each of the electronic devices may include a protection film, which will be described below, according to an embodiment of the inventive concept.

FIG. 1A is a block diagram of an electronic device ED according to an embodiment of the inventive concept. Referring to FIG. 1A, the electronic device ED may include a display module DM, a processor PR, a memory MR, and a power module PM.

The processor PR may include at least one of a central processing unit (CPU), an application processor (AP), a graphics processing unit (GPU), a communication processor (CP), an image signal processor (ISP), or a controller. The processor may include one or more processors. In implementations with more than one processor, the processors may work individually, collectively or as part of a collective. For example, as part of a collective two out of three processors may operate together to execute instructions for an application.

The memory MR may be configured to store data used to operate the processor PR or the display module DM. If an application stored in the memory MR is executed by the processor PR, image data signals and/or input control signals may be transferred to the display module DM, and the display module DM may process the transferred signals and output an image through a display screen.

The power module PM may include a power supply module (e.g., a power adapter or a battery unit) and a power conversion module, which is configured to transform the power supplied from the power supply module and produce a power for the operation of the electronic device ED.

At least one of the components constituting the electronic device ED may be included in a display module according to an embodiment of the inventive concept. In addition, a portion of each module, which is included as a functional part of the module, may be included in the display module, and other portions may be provided as a separate component different from the display module. The processor PR, the memory MR, and the power module PM may be provided as components of the electronic device ED rather than of the display module.

FIG. 1B is a schematic diagram illustrating electronic devices according to various embodiments.

Referring to FIG. 1B, an electronic device, which includes a display module according to an embodiment of the inventive concept, may be one of various electronic devices including image-displaying electronic devices (e.g., a smartphone ED_1a, a tablet PC ED_1b, a laptop computer ED_1c, a TV ED_1d, or a computer monitor ED_1e), wearable electronic devices (e.g., smart glasses ED_2a, a head-mounted display ED_2b, or a smart watch ED_2c), and a vehicle electronic device ED_3 (e.g., instrument cluster, a center fascia display, a dashboard-mounted center information display (CID), or a room mirror display).

The display module may be applied to various electronic devices. In addition, the display module, the electronic device may further include a module or device configured to execute another function.

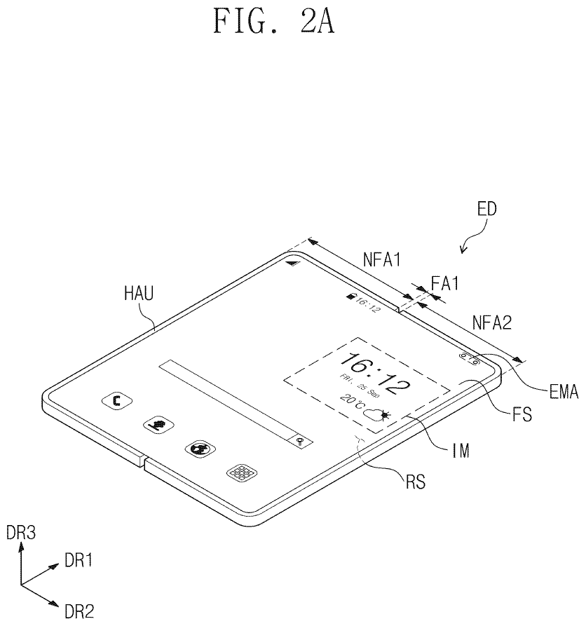

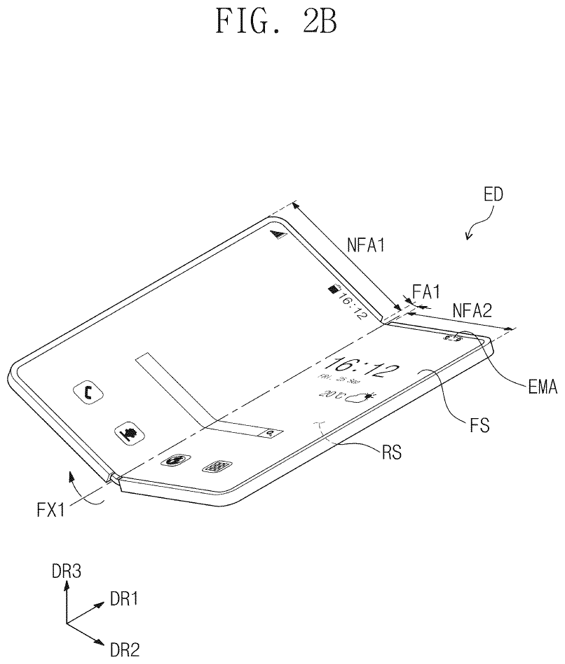

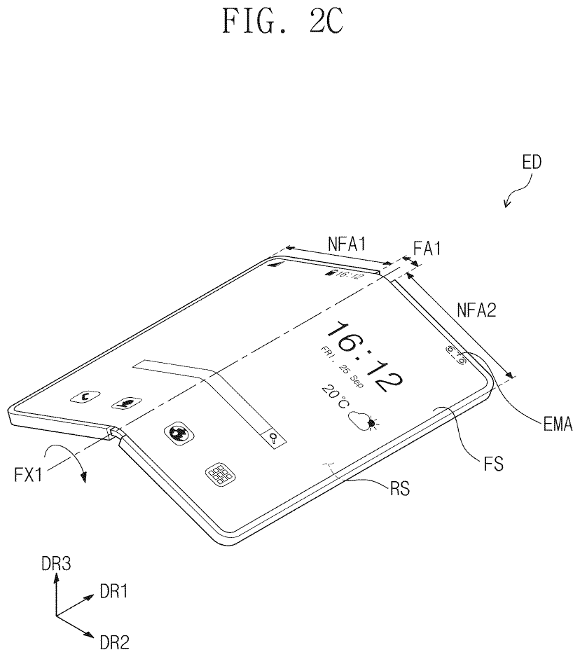

FIG. 2A is a perspective view illustrating an unfolded state of an electronic device of an embodiment. FIG. 2B is a perspective view illustrating an in-folding operation of the electronic device according to the embodiment of FIG. 2A. FIG. 2C is a perspective view illustrating an out-folding operation of the electronic device according to the embodiment of FIG. 2A.

In an embodiment, the electronic device ED may be activated by an electrical signal applied thereto. For example, the electronic device ED may be a cellular phone, a tablet, an in-vehicle navigation device, a game console, or a wearable device, but the inventive concept is not limited to these examples. In FIG. 2A and the drawings below, the electronic device ED is illustrated by way of example as a cellular phone.

In FIG. 2A and the drawings below, first, second, and third direction axes DR1, DR2, and DR3 are illustrated, and in the present specification, directions indicated by the first to third direction axes DR1, DR2, and DR3 may be relative concept and may be changed to indicate other directions. In addition, the directions indicated by the first to third direction axes DR1, DR2, and DR3 may be referred to as first to third directions DR1, DR2, and DR3 and may be identified with the same reference numbers. In the present specification, the first direction axis DR1 and the second direction axis DR2 may be orthogonal to each other, and the third direction axis DR3 may be perpendicular to a plane defined by the first direction axis DR1 and the second direction axis DR2.

Furthermore, the expression “when viewed in a plan view” in the present specification will be used to describe a structure viewed in the third direction DR3.

Referring to FIGS. 2A to 2C, the electronic device ED may include a first display surface FS defined by the first and second direction axes DR1 and DR2, which are not parallel to each other. The electronic device ED may provide an image IM to a user through the first display surface FS. The electronic device ED may be configured to display the image IM in the direction of the third direction axis DR3 through the first display surface FS parallel to each of the first and second direction axes DR1 and DR2. In the present specification, front (or top) and rear (or bottom) surfaces of each element may be distinguished, based on the third direction DR3 or the display direction of the image IM. The front and rear surfaces may be opposite to each other in the third direction axis DR3, and the direction normal to each of the front and rear surfaces may be parallel to the third direction axis DR3.

The electronic device ED may include the first display surface FS and a second display surface RS. The first display surface FS may include an electronic module region EMA. The second display surface RS may be a surface opposite to at least a portion of the first display surface FS. That is, the second display surface RS may be defined as a portion of the rear surface of the electronic device ED.

The electronic device ED may be configured to sense an external input provided from the outside. The external input may include various input signals, which are provided from the outside of the electronic device ED. For example, the external input may include contact by a user's body part, such as a hand, as well as input applied when in close proximity to the electronic device (ED) or a hovering event near the electronic device ED. In addition, the external input may be provided in various forms, such as force, pressure, temperature, and light.

The first display surface FS of the electronic device ED may include an active region that is activated by an electrical signal applied thereto. In an embodiment, the electronic device ED may be configured to display the image IM through the first display surface FS. In addition, the first display surface FS may be configured to sense various types of external inputs.

The electronic device ED may include a folding region FA1 and non-folding regions NFA1 and NFA2. In an embodiment, the non-folding regions NFA1 and NFA2 may be disposed adjacent to the folding region FA1, and the folding region FA1 may be interposed between the non-folding regions NFA1 and NFA2. In an embodiment, the electronic device ED may include a first non-folding region NFA1 and a second non-folding region NFA2, which are spaced apart from each other in the direction of the second direction axis DR2 with the folding region FA1 interposed therebetween.

FIGS. 2A to 2C illustrate an example of the electronic device ED including the folding region FA1, but the inventive concept is not limited to this example. For example, a plurality of folding regions may be defined in the electronic device ED. For example, an electronic device according to an embodiment may include two or more folding regions and three or more non-folding regions, which are spaced apart from each other with each of the folding regions interposed between.

Referring to FIG. 2B, the electronic device ED may be foldable along a first folding axis FX1. The first folding axis FX1 may be an imaginary axis that is extended in the direction of the first direction axis DR1 and may be parallel to a long side of the electronic device ED. The first folding axis FX1 may be extended along the first direction axis DR1 on the first display surface FS.

The electronic device ED may be folded inward along the first folding axis FX1 into an in-folding state, in which two regions of the first display surface FS respectively overlapped with the first and second non-folding regions NFA1 and NFA2 face each other.

When the electronic device ED is in the in-folding state, the second display surface RS may be exposed to the outside. The second display surface RS may further include an electronic module region, in which an electronic module including various components is disposed, but the inventive concept is not limited to a specific embodiment.

Referring to FIG. 2C, the electronic device ED may be folded outward along the first folding axis FX1 into an out-folding state, in which two regions of the second display surface RS respectively overlapped with the first and second non-folding regions NFA1 and NFA2 face each other.

However, the inventive concept is not limited to this example. For example, the electronic device ED may be folded along the plurality of folding axes in such a way that the first and second display surfaces FS and RS face each other at least partially. The number of the folding axis and the number of the non-folding region are not limited to these examples.

Various electronic modules may be disposed in the electronic module region EMA. For example, the electronic module may include at least one of a camera, a speaker, an optical sensor, and a heat sensor. The electronic module region EMA may be configured to sense the existence of an external object through the first or second display surface FS or RS or to output a sound signal (e.g., a voice) to the outside through the first or second display surface FS or RS. The electronic module may include a plurality of components, but the inventive concept is not limited to a specific embodiment.

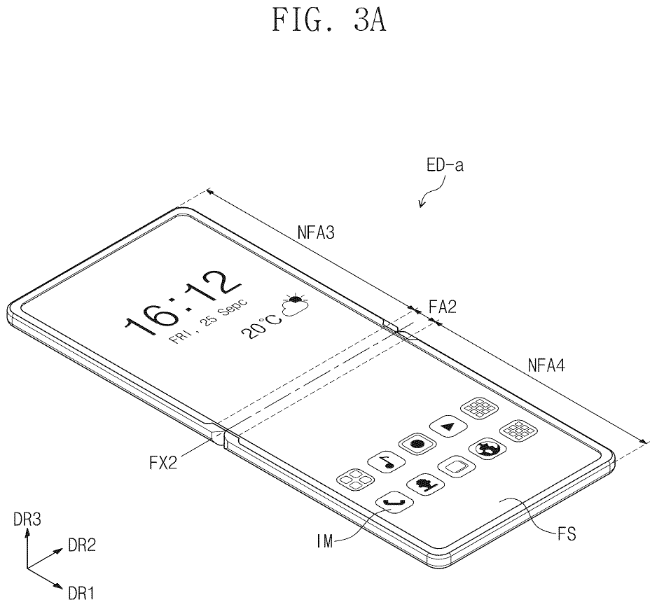

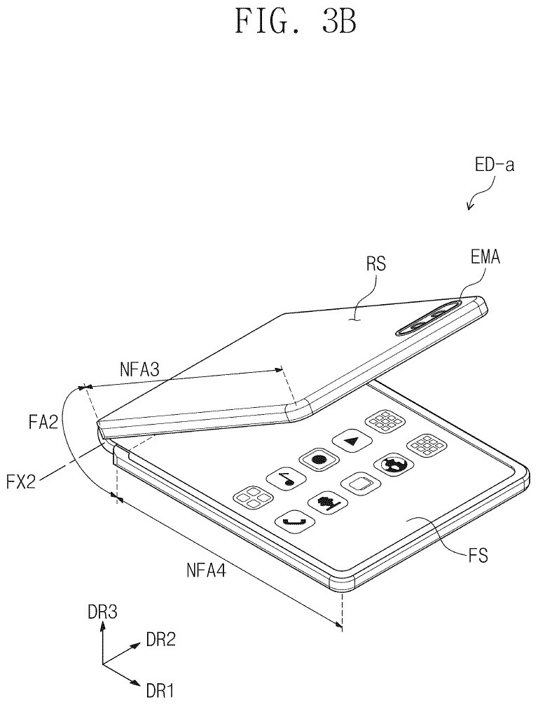

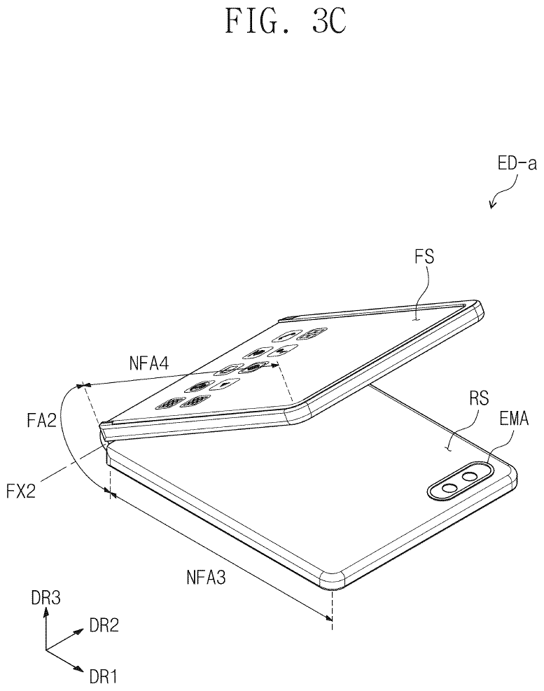

FIG. 3A is a perspective view illustrating an unfolded state of an electronic device of an embodiment. FIG. 3B is a perspective view illustrating an in-folding operation of the electronic device according to the embodiment of FIG. 3A. FIG. 3C is a perspective view illustrating an out-folding operation of the electronic device according to the embodiment of FIG. 3A.

In an embodiment, an electronic device ED-a may be foldable along a second folding axis FX2, which is extended parallel to the second direction axis DR2. FIG. 3B illustrates an example, in which the extension direction of the second folding axis FX2 is parallel to a short side of the electronic device ED-a. However, the inventive concept is not limited to this example.

In an embodiment, the electronic device ED-a may include at least one folding region FA2 and non-folding regions NFA3 and NFA4, which are adjacent to the folding region FA2. The non-folding regions NFA3 and NFA4 may be spaced apart from each other with the folding region FA2 interposed therebetween.

The folding region FA2 may have a curvature and a curvature radius. In an embodiment, the first non-folding region NFA3 and the second non-folding region NFA4 may face each other, and the electronic device ED-a may be in-folded in such a way that the first display surface FS is not exposed to the outside. In an embodiment, as shown in FIG. 3C, the electronic device ED-a may be folded outward in such a way that the first display surface FS is exposed to the outside.

The electronic device ED-a may include the second display surface RS, and the second display surface RS may be defined as a surface that is opposite to at least a portion of the first display surface FS. The second display surface RS may further include the electronic module region EMA, in which an electronic module including various components is disposed. In an embodiment, an image or video may be displayed on at least a portion of the second display surface RS.

In an embodiment, when the electronic device ED-a is in a non-folding state, the first display surface FS may be recognized by a user, and when the electronic device ED-a is in the in-folding state, the second display surface RS may be recognized by the user.

In an embodiment, the electronic device ED or ED-a may be configured to repeatedly perform from an unfolding operation to an in-folding or out-folding operation, but the inventive concept is not limited to this example. In an embodiment, the electronic device ED or ED-a may be configured to select one of the unfolding operations, the in-folding operation, and the out-folding operation. Furthermore, in the case where the electronic device ED or ED-a includes a plurality of folding regions, the folding direction of at least one of the folding regions may be different from that of the remaining folding regions. For example, if there are two folding regions, two non-folding regions with one folding region interposed therebetween may be folded in an in-folding manner, and two non-folding regions with the other interposed therebetween may be folded in an out-folding manner.

The electronic devices ED and ED-a of FIGS. 2A to 3C are example embodiments of the inventive concept, and the electronic device may be large electronic devices such as televisions, monitors, or external advertising displays, as well as medium- to small-sized electronic devices such as personal computers, laptop computers, personal digital terminals, in-vehicle navigation devices, game consoles, tablets, smartwatches, and cameras.

The electronic devices ED and ED-a shown in FIGS. 2A to 3C may include the display module DM of FIG. 1, which is used to display an image.

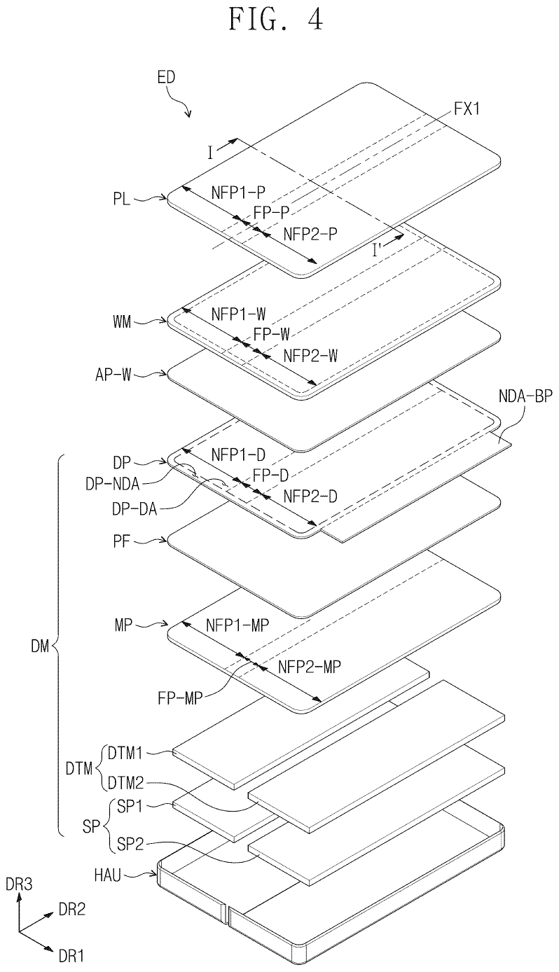

In the following description of an embodiment, including FIGS. 4 and 5, the explanation is based on the electronic device ED illustrated in FIG. 2A. However, the description of the protection film and the electronic device according to the embodiment may also be equally applied to various electronic devices, such as the electronic device ED-a of FIG. 3A having the folding axis FX2 parallel to the short side thereof or a multiple foldable electronic device (not shown).

FIG. 4 is an exploded perspective view of an electronic device according to an embodiment. FIG. 5 is a sectional view illustrating a portion of an electronic device according to an embodiment of the inventive concept. FIG. 5 is a sectional view of a portion of the electronic device corresponding to line I-I′ of FIG. 4.

The electronic device ED may include a display module DM, a window module WM, a protection film PL, and a housing HAU containing them. The housing HAU may include a lateral rectangular frame and a flat bottom surface. However, the shape of the housing HAU is limited to this example and may be changed depending on the shape of the display module DM to be contained therein and the shape of the window module WM or an upper substrate to be coupled therewith.

The display module DM may include a display panel DP and a lower module LM, which is disposed below the display panel DP. The lower module LM may include a supporting plate MP. In an embodiment, the display module DM may further include at least one of a protection layer PF, a supporting member SP, adhesive layers AP1, AP2, AP3, and AP4, and a digitizer module DTM, which are provided as additional components of the lower module LM in addition to the supporting plate MP.

The display panel DP may be configured to display an image in response to electrical signals and to send or receive information on an external input. The display panel DP may include a display region DP-DA and a non-display region DP-NDA. The display region DP-DA may be defined as a region, through which the image provided by the display panel DP is emitted.

The non-display region DP-NDA may be adjacent to the display region DP-DA. For example, the non-display region DP-NDA may be provided to enclose the display region DP-DA. However, the inventive concept is not limited to this example, and the non-display region DP-NDA may be provided in various shapes. In addition, the display panel DP may include a non-display bending portion NDA-BP that is placed near a side portion of the non-display region DP-NDA. The non-display bending portion NDA-BP may be bent toward a region below the display module DM and may be overlapped with at least a portion of the display panel DP. A circuit layer, connection lines, and/or a circuit substrate, which are used to display an image or send and receive information data, may be mounted on or attached to the non-display bending portion NDA-BP.

In an embodiment, the display panel DP may include a display layer EDL. The display layer EDL may be a substantial element generating an image. The image produced by the display layer EDL may be recognized by a user through the first display surface FS (shown in FIG. 2A). The display layer EDL may be a light-emitting type display layer, but the inventive concept is not limited to this example. For example, the display layer EDL may be an organic light emitting display layer or an inorganic light-emitting display layer. In the organic light emitting display layer, a light-emitting device may include a light emitting layer containing an organic light emitting material. In the inorganic light-emitting display layer, a light-emitting device may include a light emitting layer containing quantum dots and quantum rods.

The display panel DP may further include a sensor layer ISL. The sensor layer ISL may be directly disposed on the display layer EDL. The sensor layer ISL may include a plurality of sensing electrodes. The sensor layer ISL may be configured to sense an external input in a self-capacitance manner or in a mutual-capacitance manner. In an embodiment, the sensor layer ISL may be configured to sense an input event produced by an active-type input device.

The sensor layer ISL may be directly formed on the display layer EDL through a consecutive process during the fabrication of the display layer EDL. However, the inventive concept is not limited to this example, and the sensor layer ISL may be fabricated as a separate panel, which is different from the display layer EDL, and may be attached to the display layer EDL by an adhesive layer (not shown).

In addition, the display panel DP may further include an optical layer ROL. The optical layer ROL may be configured to reduce the reflectance of an external light. For example, the optical layer ROL may include a polarization layer or a color filter layer. However, the inventive concept is not limited to this example, and the optical layer ROL may include optical members, which are provided to improve the display quality of the display module DM.

In an embodiment, the optical layer ROL may be directly disposed on the sensor layer ISL. In the case where the sensor layer ISL is omitted from the display panel DP, the optical layer ROL may be directly disposed on the display layer EDL. However, the inventive concept is not limited to this example, and the optical layer ROL may be placed on the display layer EDL or the sensor layer ISL using an additional adhesive member.

The display panel DP may include a folding display portion FP-D and non-folding display portions NFP1-D and NFP2-D. The folding display portion FP-D may be a portion corresponding to the folding region FA1 (e.g., of FIG. 2A), and the non-folding display portions NFP1-D and NFP2-D may be portions corresponding to the non-folding regions NFA1 and NFA2 (e.g., of FIG. 2A). The folding display portion FP-D and the non-folding display portions NFP1-D and NFP2-D of the display panel DP may be referred to as a folding display portion and a non-folding display portion, respectively, of the display module DM.

The folding display portion FP-D may correspond to a portion that is folded or bent along the folding axis FX1 (e.g., of FIG. 2B). The display panel DP may include a first non-folding display portion NFP1-D and a second non-folding display portion NFP2-D, which are spaced apart from each other in the first direction DR1 with the folding display portion FP-D interposed therebetween. The folding display portion FP-D may correspond to the folding region FA1 of the electronic device ED, and the first and second non-folding display portions NFP1-D and NFP2-D may correspond to the first and second non-folding regions NFA1 and NFA2 of the electronic device ED.

In an embodiment, the supporting plate MP may be disposed below the display panel DP. The supporting plate MP may include a folding supporting portion FP-MP and non-folding supporting portions NFP1-MP and NFP2-MP. The supporting plate MP may include a first non-folding supporting portion NFP1-MP and a second non-folding supporting portion NFP2-MP, which are spaced apart from each other in the first direction DR1 with the folding supporting portion FP-MP interposed therebetween. The folding supporting portion FP-MP may be a portion corresponding to the folding region FA1 (e.g., of FIG. 2A), and the non-folding supporting portions NFP1-MP and NFP2-MP may be portions corresponding to the non-folding regions NFA1 and NFA2 (e.g., of FIG. 2A). The supporting plate MP may include a pattern portion PTA, in which a plurality of openings OH are defined. The pattern portion PTA may be included in the folding supporting portion FP-MP. Since the pattern portion PTA is placed at a position corresponding to the folding region FA1, the folding or bending property of the electronic device ED may be improved.

In the display module DM according to an embodiment of the inventive concept, the protection layer PF of the lower module LM may be disposed between the display panel DP and the supporting plate MP. The protection layer PF may be placed below the display panel DP to protect the rear surface of the display panel DP. The protection layer PF may be fully overlapped with the display panel DP. The protection layer PF may be formed of or include at least one polymeric material. For example, the protection layer PF may be a polyimide film or a polyethylene terephthalate film. However, the material of the protection layer PF is not limited to this example.

In an embodiment, the lower module LM may include the supporting member SP. The supporting member SP may include supporting layers SP1 and SP2. The supporting layers SP1 and SP2 may include a first supporting layer SP1 and a second supporting layer SP2, which are spaced apart from each other in the direction of the first direction axis DR1. The first and second supporting layers SP1 and SP2 may be spaced apart from each other at a portion corresponding to the first folding axis FX1 of FIG. 2A. Since the supporting layers SP1 and SP2 are provided in the form of the first and second supporting layers SP1 and SP2 that are spaced apart from each other at the folding region FA1, the folding or bending property of the electronic device ED may be improved. Although not shown, the supporting layers SP1 and SP2 may further include a cushion layer (not shown) and a lower supporting plate (not shown), which are stacked in its thickness direction.

In an embodiment, the electronic device ED may further include the digitizer module DTM placed below the supporting plate MP. In an embodiment, the digitizer module DTM may include a digitizer layer, a shielding layer, and so forth. The digitizer module DTM may be included as a part of the lower module LM.

The digitizer module DTM may include a first digitizer module DTM1 and a second digitizer module DTM2, which are spaced apart from each other and are placed in a region overlapped with the folding region FA1. The first digitizer module DTM1 may be disposed to correspond to the first non-folding region NFA1, and the second digitizer module DTM2 may be disposed to correspond to the second non-folding region NFA2.

In an embodiment, the first digitizer module DTM1 and the second digitizer module DTM2 may be spaced apart from each other at a region overlapped with the folding display portion FP-D. The first digitizer module DTM1 may overlap the first non-folding display portion NFP1-D, and the second digitizer module DTM2 may overlap the second non-folding display portion NFP2-D.

In an embodiment, the electronic device ED may include at least one adhesive layer (e.g., AP1, AP2, AP3, AP4, and AP-W). For example, the first adhesive layer AP1 may be disposed between the display panel DP and the protection layer PF, and the second adhesive layer AP2 may be disposed between the protection layer PF and the supporting plate MP. Each of the third and fourth adhesive layers AP3 and AP4 may be disposed between the supporting plate MP and the supporting member SP. The fifth adhesive layer AP-W may be disposed between the optical layer ROL and the window module WM. The at least one adhesive layer (e.g., AP1, AP2, AP3, AP4, and AP-W) may be an optically clear adhesive film or an optically clear adhesive resin layer. However, the inventive concept is not limited to this example, and the at least one adhesive layer (e.g., AP1, AP2, AP3, AP4, and AP-W) may be an adhesive layer having a transmittance of 80% or lower.

FIGS. 4 and 5 illustrate an example of the lower module LM, in which the protection layer PF, the supporting plate MP, the supporting member SP, the at least one adhesive layer (e.g., AP1, AP2, AP3, and AP4), and the digitizer module DTM are provided, but the inventive concept is not limited to this example. For example, the lower module LM may be configured to include only some of the above-listed components or to further include other components, which are not included in the above-listed components, in consideration of mechanical, structural shape, operational requirements of the electronic device ED.

The electronic device ED may include the window module WM disposed on the display module DM. The window module WM may include a folding window portion FP-W and non-folding window portions NFP1-W and NFP2-W. The window module WM may include a first non-folding window portion NFP1-W and a second non-folding window portion NFP2-W, which are spaced apart from each other in the first direction DR1 with the folding window portion FP-W interposed therebetween. The folding window portion FP-W may be a portion corresponding to the folding region FA1 of the electronic device ED (shown in FIG. 2A), and the non-folding window portions NFP1-W and NFP2-W may be portions corresponding to the non-folding regions NFA1 and NFA2. In addition, the folding window portion FP-W may be a portion corresponding to the folding display portion FP-D, and the non-folding window portions NFP1-W and NFP2-W may be portions corresponding to the non-folding display portions NFP1-D and NFP2-D.

The window module WM may be provided to cover the entire top surface of the display module DM. In an embodiment, the window module WM may be used as a cover window of the electronic device ED. The window module WM may include a glass substrate, and the glass substrate in the window module WM maty be a tempered glass substrate. In addition, the glass substrate may be an ultra-thin tempered glass substrate.

The electronic device ED may further include an anti-reflection layer AR and an anti-fingerprint layer (not shown) thereon. The anti-fingerprint layer may function to prevent fingerprints and smudges generated during use of the electronic device ED, thereby maintaining visual clarity.

In an embodiment, the electronic device ED may include the protection film PL disposed on the window module WM. The protection film PL may include a folding portion FP-P and non-folding portions NFP1-P and NFP2-P. The first and second non-folding portions NFP1-P and NFP2-P of the protection film PL may be spaced apart from each other in the first direction DR1, with the folding portion FP-P interposed therebetween. The folding portion FP-P may be a portion corresponding to the folding region FA1 of the electronic device ED (shown in FIG. 2A), and the non-folding portions NFP1-P and NFP2-P may be portions corresponding to the non-folding regions NFA1 and NFA2. In addition, the folding portion FP-P may be a portion corresponding to the folding window portion FP-W, and the non-folding portions NFP1-P and NFP2-P may be portions corresponding to the non-folding window portions NFP1-W and NFP2-W. In an embodiment, the protection film PL may correspond to the uppermost member of the electronic device ED.

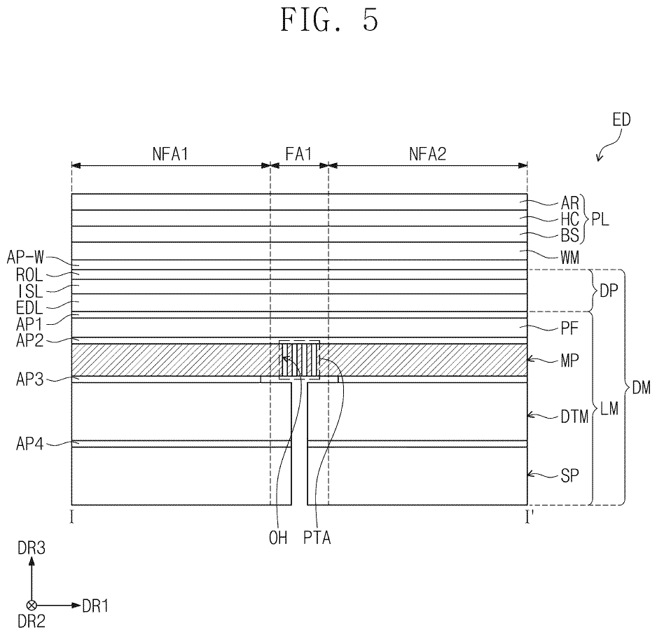

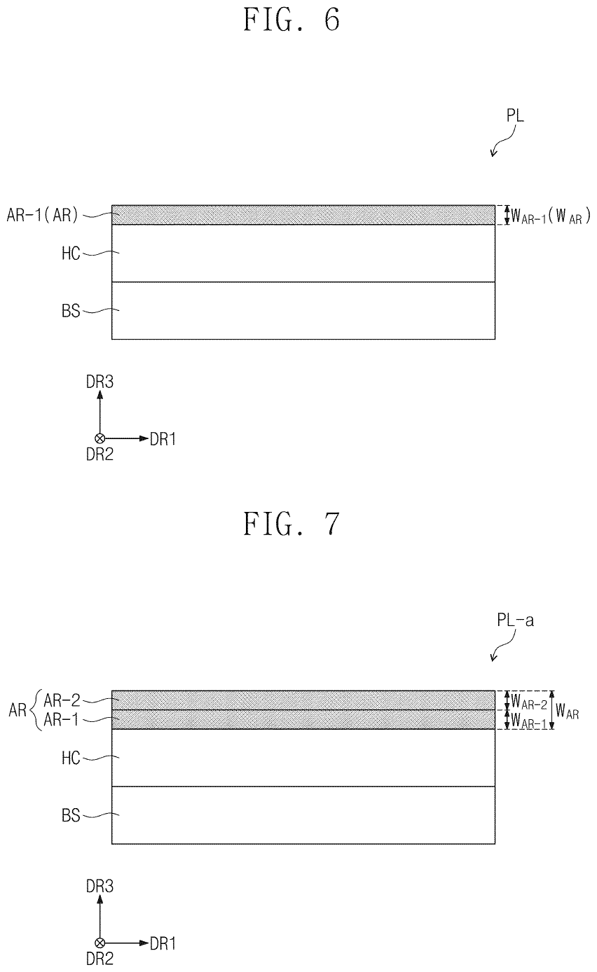

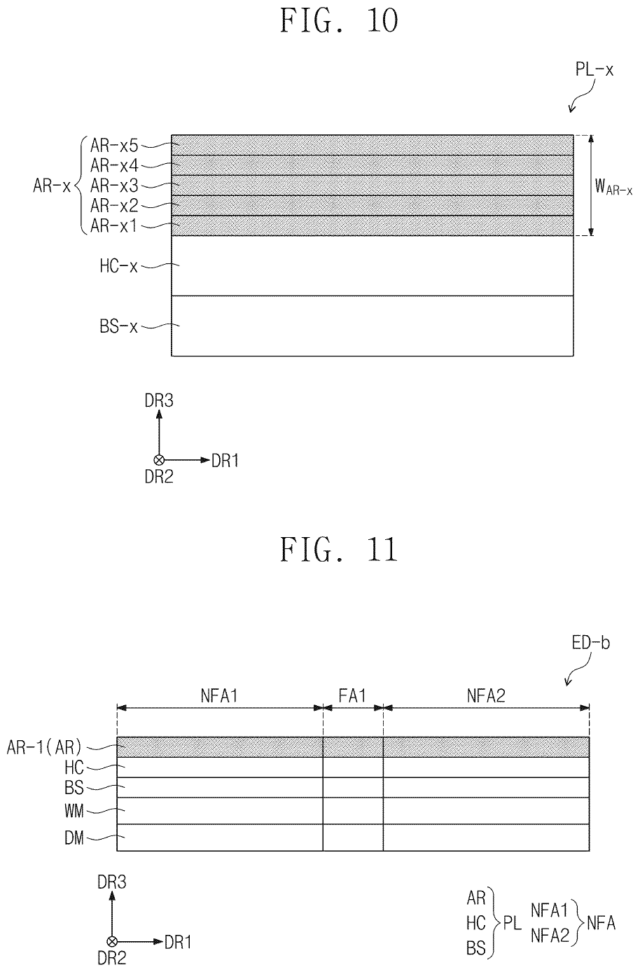

Hereinafter, protection films PL, PL-a, PL-b, and PL-c according to embodiments of the inventive concept will be described in more detail with reference to FIGS. 6 to 9. FIGS. 6 to 9 are sectional views, each illustrating the protection film PL, PL-a, PL-b, or PL-c according to an embodiment of the inventive concept. FIG. 10 is a sectional view illustrating a protection film PL-x according to a comparative example.

Referring to FIGS. 6 to 8, the protection film PL may include a base portion BS, a hard coating layer HC disposed on the base portion BS, and the anti-reflection layer AR, which is disposed on the hard coating layer HC and includes a first anti-reflection portion AR-1. The hard coating layer HC may include silsesquioxane and titanium chelate oligomer or may include silsesquioxane and acrylic-based copolymer. The first anti-reflection portion AR-1 may have a first refractive index lower than the refractive index of the hard coating layer HC and may be disposed adjacent to the hard coating layer HC.

The base portion BS, the hard coating layer HC, and the anti-reflection layer AR may be stacked in the third direction DR3 to form a stacking structure and to be parallel to a plane defined by the first and second direction axes DR1 and DR2. In this case, each of the base portion BS, the hard coating layer HC, and the anti-reflection layer AR may have a thickness in the third direction DR3.

In the protection film PL, the base portion BS may be a member having a base surface, on which the hard coating layer HC is placed on. In an embodiment, the base portion BS may be used to support the hard coating layer HC and may be configured to enhance the durability of the protection film PL.

The base portion BS may have a flat shape or a curved shape. FIGS. 6 to 8 illustrate an example, in which the base portion BS is flat, but the inventive concept is not limited to this example.

The base portion BS may be transparent. The base portion BS may be made of optically transparent materials, such as polycarbonate (PC) and polyethylene terephthalate (PET), but the inventive concept is not limited to this material. In addition, the base portion BS may be provided to have a flexible property.

The hard coating layer HC may be disposed on the base portion BS, and it may include silsesquioxane and titanium chelate oligomer or may include silsesquioxane and acrylic-based copolymer. In this case, the hard coating layer HC may have a high refractive index and may increase the durability and structural stiffness of the protection film PL. The titanium chelate oligomer may be formed by a polymerization reaction of titanium chelate molecules. Since the titanium chelate molecule includes an alkyl group, an alkylester group, or an aryl group causing the polymerization reaction, the titanium chelate oligomer may be formed from the titanium chelate.

In the present specification, the oligomer refers to a compound formed by the chemical bonding of 2 to 20 monomers, and is distinguished from a polymer, which is formed by the bonding of thousands to millions of monomers.

In the present specification, the term “high refractive index” may mean a refractive index from 1.6 (inclusive) to 2.3 (exclusive). In the present specification, the term “intermediate refractive index” may mean a refractive index ranging from 1.5 (inclusive) to 1.6 (exclusive). In the present specification, the term “low refractive index” may mean a refractive index ranging from 1.3 (inclusive) to 1.5 (exclusive).

The silsesquioxane may have an organic-inorganic nano-hybrid structure containing Si, O, and an alkyl group, and due to the presence of the silsesquioxane, the hard coating layer HC may have high hardness, high flexibility, high transparency, excellent heat resistance, chemical resistance, and outstanding wear resistance.

In the case where the hard coating layer HC contains silsesquioxane and titanium chelate oligomer, the silsesquioxane may be a silsesquioxane compound. In this case, the silsesquioxane compound may be a silsesquioxane polymer. For the silsesquioxane compound, PGM (1-Methoxy-2-propanol) and MEK (2-Butanone) may be used as a solvent. The silsesquioxane compound may be provided in the form of a resin. The silsesquioxane compound may be a random-type resin, which is formed in a random shape during a fabrication process, a partial cage-type resin, a ladder-type resin, or a cage-type resin. In an embodiment, the silsesquioxane resin may be the random-type resin.

In the case where the hard coating layer HC contains silsesquioxane and acrylic-based copolymer, the silsesquioxane may be a silsesquioxane compound. In this case, the silsesquioxane compound may have a molecular mass ranging from 3,000 to 6,000. In an embodiment, the silsesquioxane compound may be a random-type silsesquioxane compound, which is formed in a random shape during a fabrication process.

The titanium chelate oligomer may be titanium alkoxide oligomer (Ti ORa₄]ₙ₁), titanium β-diketone oligomer ([Ti (R_{b}COCH₂COR_{c})₄]ₙ₂), or titanium carboxylate oligomer ([Ti (OOCR_{d})₄]ₙ₃). Here, each of Rₐ, R_{b}, R_{c}, and R_{d} may be independently hydrogen, deuterium, a substituted or unsubstituted C₁-C₂₀ alkyl group, a substituted or unsubstituted C₆-C₃₀ aryl group, or a substituted or unsubstituted C₂-C₃₀ heteroaryl group, and each of n1 to n3 is independently an integer greater than or equal to 4 and less than or equal to 8.

In this case, owing to the titanium chelate oligomer, the hard coating layer HC may have a high refractive index and may exhibit a hydrophilic property. In addition, due to the covalent or coordinate bond of the titanium chelate oligomer, the hard coating layer HC and the anti-reflection layer AR may be closely adhered to each other. In an embodiment, if n1 to n3 is 6 or 7, it may be possible to effectively increase the clearness and thickness uniformity of a film or layer, and if it is included in a foldable electronic device, it may be possible to effectively prevent a crack issue from occurring in a folding region.

In an embodiment, the titanium alkoxide oligomer may represented as [Ti (OC₈H₁₇)₄]ₙ₁, but the inventive concept is not limited thereto.

In titanium β-diketonates, the term “β” may refer to the position of the second carbon atom that connects the two carbonyl groups, and a β-diketone compound may have a structure in which two carbonyl groups are bonded to adjacent carbon atoms. In an embodiment, the titanium 3-diketone oligomer may be titanium acetylacetone oligomer ([Ti(C₅H₇O₂)₄]ₙ₂), but the inventive concept is not limited thereto.

In an embodiment, the titanium carboxylate oligomer may be titanium acetylate oligomer ([Ti(OOCCH₃)₄]ₙ₂) or titanium stearate oligomer ([Ti(OOCC₁₇H₃₅)₄]ₙ₂), but the inventive concept is not limited thereto.

In the case where the hard coating layer HC includes the silsesquioxane and the titanium chelate oligomer, it may be directly disposed below the anti-reflection layer AR. Referring to FIG. 9, the hard coating layer HC may include a lower layer HC-d, which is disposed adjacent to the base portion BS and contains silsesquioxane, and an upper layer HC-u, which is disposed adjacent to the anti-reflection layer AR and contains titanium chelate oligomer. The titanium chelate oligomer may exhibit excellent crosslinking ability and functions as an inorganic binder, and the upper layer HC-u may be directly disposed below the anti-reflection layer AR that is an inorganic layer. In this case, the hard coating layer HC may serve as a primer, because it has an excellent adhesive property with the anti-reflection layer AR.

The acrylic-based copolymer may be an acrylic-based resin. The acrylic-based copolymer may be represented by

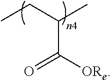

Here, Rₑ may be a substituted or unsubstituted C₁-C₂₀ alkyl group, a substituted or unsubstituted C₆-C₃₀ aryl group, or a substituted or unsubstituted C₂-C₃₀ heteroaryl group. The acrylic-based copolymer may be a polymer, and n4 may be an integer greater than or equal to 100 and less than 1,000,000.

In an embodiment, the acrylic-based copolymer may be a copolymer of TIPA (2,4,6-Triiodophenyl acrylate) and HEA (2-hydroxyethyl acrylate) or a copolymer of TIPA and EEA (2-(2-ethoxyethoxy)ethyl acrylate). Since the TIPA includes iodine, the higher the content of TIPA, the higher the refractive index of the hard coating layer HC. In addition, since it includes the acrylic-based copolymer, the hard coating layer HC may have thermosetting properties, high hardness, and high transparency.

The weight ratio between TIPA and HEA or the weight ratio between TIPA and EEA may range from 97:3 to 75:25. In this case, the hard coating layer HC may have a high refractive index and may exhibit excellent moldability during its fabrication. For example, the weight ratio between TIPA and HEA may be 90:10, 95:15, or 80:20. For example, the weight ratio between TIPA and EEA may be 95:5, 90:10, or 80:20.

In an embodiment, the weight-average molecular weight of the acrylic-based copolymer may range from 10,000 to 30,000. In this case, the hard coating layer HC may have a high refractive index. The weight-average molecular weight may be measured using a high-speed GPC system HLC-8220 GPC, after dissolving 10 mg of acrylic-based copolymer compound in 10 mL of NMP (N-Methyl-2-pyrrolidone)/LiBr. In the case where the copolymer between TIPA and HEA has the weight-average molecular weight of 11,000 to 15,000, the hard coating layer HC may have a high refractive index. In the case where the copolymer between TIPA and EEA has a weight-average molecular weight of 15,000 to 28,000, the hard coating layer HC may have a high refractive index.

In an embodiment, the weight ratio between the silsesquioxane and the acrylic-based copolymer may range from 5:95 to 20:80. In this case, the hard coating layer HC may have a high refractive index. For example, the weight ratio between the silsesquioxane and the acrylic-based copolymer may be 10:90.

In an embodiment, the refractive index of the hard coating layer HC may have a high refractive index ranging from 1.6 to 2.0 at a wavelength of 550 nm. In detail, the hard coating layer HC may include silsesquioxane and titanium chelate oligomer, resulting in having a refractive index ranging from 1.6 to 1.75, or it may include silsesquioxane and acrylic-based copolymer, thereby having a refractive index ranging from 1.65 to 1.9. Since the hard coating layer HC has a high refractive index, it may be possible to reduce the number of the layers constituting the anti-reflection layer AR. Although the hard coating layer HC is in general used as a protection layer (increasing the durability), the optical property of the hard coating layer HC may affect the design of the anti-reflection layer AR. If the hard coating layer HC has a low refractive index, more anti-reflection layers may be used to suppress the optical reflection issue. However, if the hard coating layer HC has an increased refractive index, it may be possible to reduce the difference in refractive index between the base portion BS and the air and to effectively suppress the optical reflection issue. Thus, if the hard coating layer HC has a high refractive index, it may be possible to realize desired reflectance characteristics, even when the number of low refractive layers stacked in a conventional anti-reflection layer is reduced.

Even when the anti-reflection layer AR has a single-, double- or triple-layered structure, the anti-reflection layer AR may exhibit excellent optical property (e.g., a low reflectance of 1% or lower at a wavelength of 550 nm) and may have a small thickness of W_{AR} in the third direction DR3. Thus, if the electronic device ED (shown in FIG. 2A) includes the protection film according to an embodiment of the inventive concept, it may be possible to reduce a compressive stress exerted on the folding region FA1 (shown in FIG. 2A) during the folding operation. In this case, it may be possible to prevent or suppress a crack issue from occurring in a portion of a protection film placed in the folding region FA1 (shown in FIG. 2A).

The anti-reflection layer AR may be a coating layer that is configured to reduce optical reflection and enhance optical transmittance. The anti-reflection layer AR may be used to reduce an external light, which is reflected from the display surface FS (shown in FIG. 2A) of the electronic device ED (shown in FIG. 4), using a destructive interference phenomenon, and to improve the clarity and contrast characteristics of the image IM (shown in FIG. 2A).

Referring to FIGS. 6 to 8, the anti-reflection layer AR may be disposed on the hard coating layer HC and may include the first anti-reflection portion AR-1. The first anti-reflection portion AR-1 may have a first refractive index lower than the refractive index of the hard coating layer HC and may be disposed adjacent to the hard coating layer HC. In an embodiment, the first refractive index may range from 1.35 to 1.5 at a wavelength of 550 nm.

In an embodiment, the anti-reflection layer AR may have a single-layered structure including only the first anti-reflection portion AR-1 or a double- or triple-layered structure including the first anti-reflection portion AR-1. Since the hard coating layer HC has a high refractive index, the reflectance may be sufficiently reduced by the anti-reflection layer AR, even when the anti-reflection layer AR has the single-, double- or triple-layered structure.

In an embodiment, a thickness W_{AR} of the anti-reflection layer AR may range from 80 nm to 350 nm. Since the thickness W_{AR} of the anti-reflection layer AR is reduced, the total thickness of the protection film PL may be reduced.

In an embodiment, the anti-reflection layer AR may further include a second anti-reflection portion AR-2 directly disposed on the first anti-reflection portion AR-1, and a thickness W_{AR-2} of the second anti-reflection portion AR-2 may range from 75 nm to 95 nm.

In an embodiment, the anti-reflection layer AR may further include a second anti-reflection portion AR-2, which is disposed on the first anti-reflection portion AR-1 and has a second refractive index higher than the first refractive index of the first anti-reflection portion AR-1, and a third anti-reflection portion AR-3, which is disposed on the second anti-reflection portion AR-2 and has a third refractive index lower than the second refractive index. In this case, the second refractive index of the second anti-reflection portion AR-2 may be higher than the refractive index of the hard coating layer HC.

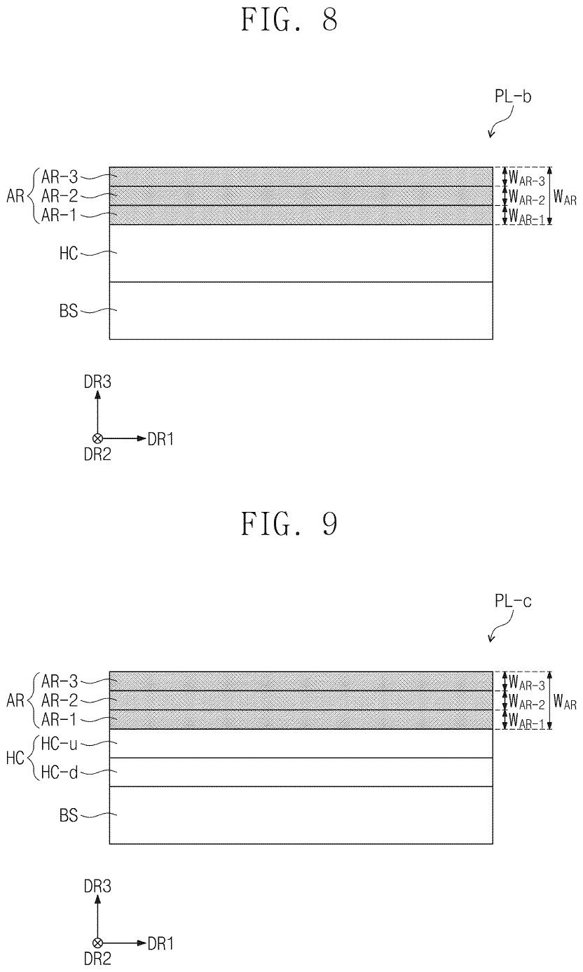

In the case where the hard coating layer HC include silsesquioxane and titanium chelate oligomer, the anti-reflection layer AR may have a single-layered structure including the first anti-reflection portion AR-1, as shown in FIG. 6, or may have a triple-layered structure including the first to third anti-reflection portions AR-1, AR-2, and AR-3, as shown in FIG. 8.

In an embodiment, the thickness W_{AR} of the anti-reflection layer AR may range from 80 nm to 350 nm. In the case where the anti-reflection layer AR has a single-layered structure, the thickness W_{AR} of the anti-reflection layer AR may be substantially equal to a thickness W_{AR-1} of the first anti-reflection portion AR-1.

The anti-reflection layer AR may include at least one of Si₉Al₂O₁₀, SiO₂, Ti1₄Nb₃O₃₅, and AlF₃. Hereinafter, various embodiments will be described according to the material of the hard coating layer HC and the structure of the anti-reflection layer AR.

In the case where the hard coating layer HC contains silsesquioxane and titanium chelate oligomer and the anti-reflection layer AR has the single-layered structure as shown in FIG. 6, the first anti-reflection portion AR-1 may include Si₉Al₂O₁₀, and the thickness W_{AR-1} of the first anti-reflection portion AR-1 may range from 82 nm to 102 nm. In addition, the first refractive index may be a low refractive index ranging from 1.3 to 1.5.

In the case where the hard coating layer HC contains silsesquioxane and titanium chelate oligomer and the anti-reflection layer AR has a three-layered structure as shown in FIG. 8, the first anti-reflection portion AR-1 may include Si₉Al₂O₁₀, and the thickness W_{AR-1} of the first anti-reflection portion AR-1 may range from 5 nm to 20 nm. In addition, the second anti-reflection portion AR-2 may include Ti₁₄Nb₃O₃₅, and the thickness W_{AR}-2 of the second anti-reflection portion AR-2 may range from 75 nm to 95 nm. In addition, the third anti-reflection portion AR-3 may include SiO₂, and a thickness W_{AR-3} of the third anti-reflection portion AR-3 may range from 90 nm to 110 nm. In an embodiment, the first and third refractive indices may be a low refractive index ranging from 1.3 to 1.5, and the second refractive index may be a high refractive index ranging from 1.6 to 2.3.

In the case where the hard coating layer HC contains silsesquioxane and titanium chelate oligomer and the anti-reflection layer AR has a triple-layered structure (as shown in FIG. 8), the first anti-reflection portion AR-1 may include SiO₂, and the thickness W_{AR-1} of the first anti-reflection portion AR-1 may range from 90 nm to 110 nm. In addition, the second anti-reflection portion AR-2 may include Ti₁₄Nb₃O₃₅, and the thickness W_{AR-2} of the second anti-reflection portion AR-2 may range from 75 nm to 95 nm. In an embodiment, the third anti-reflection portion AR-3 may include Si₉Al₂O₁₀, and the thickness W_{AR-3} of the third anti-reflection portion AR-3 may range from 5 nm to 20 nm.

In an embodiment, the Si₉Al₂O₁₀ may have a low refractive index ranging from 1.3 to 1.5, and it may be included in the anti-reflection layer AR to improve the wear resistance, which is the ability to resist erosion caused by friction and mechanical wear during use of the electronic device ED (shown in FIG. 2A). The Ti₁₄Nb₃O₃₅ may have a high refractive index ranging from 1.6 to 2.3, and it may be included in the anti-reflection portion AR to realize a high refractive index. In the case where the second anti-reflection portion AR-2 includes Ti₁₄Nb₃O₃₅, the second refractive index may be higher than the refractive index of the hard coating layer HC. The SiO₂ may have a low refractive index ranging from 1.3 to 1.5, and it may be included in the anti-reflection portion AR to increase an adhesion strength to adjacent components. However, the thicknesses W_{AR-1}, W_{AR-2}, and W_{AR-3} and the materials of the first, second, and third anti-reflection portions AR-1, AR-2, and AR-3 are not limited to those in the above embodiments.

In the case where the hard coating layer HC contains silsesquioxane and acrylic-based copolymer, the anti-reflection layer AR may have a single-layered structure including the first anti-reflection portion AR-1, as shown in FIG. 6, or may have a double-layered structure including the first and second anti-reflection portions AR-1 and AR-2, as shown in FIG. 7.

In the case where the hard coating layer HC contains silsesquioxane and acrylic-based copolymer and the anti-reflection layer AR has a single-layered structure as shown in FIG. 6, the first anti-reflection portion AR-1 may include AlF₃, and the thickness W_{AR-1} of the first anti-reflection portion AR-1 may range from 86 nm to 106 nm. In addition, the first refractive index may be a low refractive index ranging from 1.3 to 1.5.

In the case where the hard coating layer HC contains silsesquioxane and acrylic-based copolymer and the anti-reflection layer AR has a double-layered structure as shown in FIG. 7, the first anti-reflection portion AR-1 may include Si₉Al₂O₁₀, and the thickness W_{AR-1} of the first anti-reflection portion AR-1 may range from 5 nm to 20 nm. In addition, the second anti-reflection portion AR-2 may include AlF₃, and the thickness W_{AR-2} of the second anti-reflection portion AR-2 may range from 75 nm to 95 nm. In addition, the first and second refractive indices may be a low refractive index ranging from 1.3 to 1.5.

The AlF₃ may have a low refractive index ranging from 1.3 to 1.5 and may be included in the anti-reflection portion AR, and in this case, it may cause destructive interference to light of a specific wavelength, thereby allowing the electronic device ED to provide a high-clarity image. The Si₉Al₂O₁₀ may have a low refractive index ranging from 1.3 to 1.5 and may be included in the anti-reflection portion AR, and in this case, it may be possible to improve the wear resistance characteristics of the electronic device ED (shown in FIG. 2A). However, the thicknesses W_{AR-1} and W_{AR-2} and the materials of the first and second anti-reflection portions AR-1 and AR-2 are not limited to the above examples.

The anti-reflection layer AR may be formed using a physical vapor deposition (PVD) method such as vacuum deposition, in which a material is vaporized in a vacuum state and deposited onto a substrate, or sputtering, in which a deposition material is evaporated using high-energy ions and coated onto the substrate. In addition, it may be formed by a chemical vapor deposition (CVD) method, which forms a thin layer on a substrate through a chemical reaction, or by an atomic layer deposition (ALD) method, which deposits material at the atomic level. However, a method of fabricating the anti-reflection layer AR is not limited thereto.

FIG. 10 is a sectional view illustrating the protection film PL-x according to the comparative example.

Referring to FIG. 10, in the protection film PL-x of the comparative example, a hard coating layer HC-x may be disposed on a base layer BS-X and the hard coating layer HC-x may have an intermediate refractive index ranging from 1.5 to 1.6, and thus, to realize a low reflectance of 1% or lower, an anti-reflection layer AR-x may be provided to have a stacking structure including five or more layers. In detail, the anti-reflection layer AR-x may have a structure in which the first, third, and fifth anti-reflection portion AR-x1, AR-x3, and AR-x5 having a low refractive index and the second and fourths anti-reflection portion AR-x2 and AR-x4 having an intermediate or high refractive index are alternately stacked. However, in the protection film PL-x according to the comparative example, the number of layers constituting the hard coating layer HC-x may be greater than five. For example, the hard coating layer HC-x may have a stacking structure including five to eight layers. In the comparative example, due to this multi-layered structure of the protection film PL-x, the anti-reflection layer AR-x may have a large thickness W_{AR-x}, and thus, in the case where the protection film PL-x is included in an electronic device with a folding region, a crack issue may occur in the folding region by a compressive stress and a consequent folding stress exerted on the folding region during the folding operation. In the present specification, the folding stress may refer to a mechanical phenomenon that occurs in the electronic device due to repeated compressive and tensile stresses applied on the folding region during the folding operation of the foldable electronic device.

By contrast, the protection films PL, PL-a, and PL-b in the embodiments of FIGS. 6 to 8 may be configured to include the hard coating layer HC of a high refractive index and the anti-reflection layer AR of a small layer number, and thus, it may have a small thickness, compared to the conventional protection film. Even when the anti-reflection layer AR has a single-, double- or triple-layered structure, the anti-reflection layer AR may exhibit an excellent optical property (e.g., a low reflectance of 1% or lower at a wavelength of 550 nm) and may have a small thickness of W_{AR} in the third direction DR3. Accordingly, if the electronic device ED (shown in FIG. 2A) includes the protection film PL, it may be possible to effectively reduce the compressive stress applied to the folding region FA1 (shown in FIG. 2A) during the folding operation and thereby to prevent or suppress the crack issue from occurring in the folding region FA1 (shown in FIG. 2A).

In an embodiment, the protection film PL may have the reflectance of 1% or lower at a wavelength of 550 nm. For example, the reflectance of the protection film PL may be less than 0.5% at a wavelength of 550 nm.

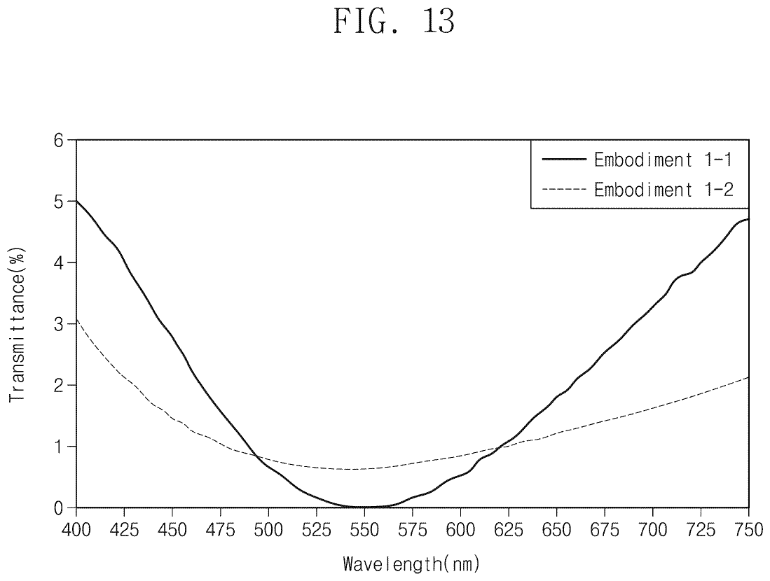

FIG. 13 is a graph showing the simulated wavelength-reflectance characteristics of a protection film of an embodiment 1-1 and a protection film of an embodiment 1-2, when the hard coating layer contains silsesquioxane and titanium chelate oligomer. There is a structural difference between the anti-reflection layers according to the embodiments 1-1 and 1-2.

In the protection film of the embodiment 1-1, the base portion was PET, and the hard coating layer included a random-type silsesquioxane compound and [Ti (C₅H₇O₂)₄]n, where n was 5 or 6 and the refractive index of the hard coating layer was 1.65 at a wavelength of 636 nm. In addition, the anti-reflection layer had a triple-layered structure: the first anti-reflection portion included Si₉Al₂O₁₀ and had a thickness of 10 nm; the second anti-reflection portion included Ti₁₄Nb₃O₃₅ and had a thickness of 83 nm; and the third anti-reflection portion included SiO₂ and had a thickness of 100 nm.

In the protection film of the embodiment 1-2, the base portion was PET, and the hard coating layer included a random-type silsesquioxane compound and [Ti (C₅H₇O₂)₄]n, where n was 5 or 6 and the refractive index of the hard coating layer was 1.65 at a wavelength of 636 nm. In addition, the anti-reflection layer had a single-layered structure including the first anti-reflection portion, which included Si₉Al₂O₁₀ and had a thickness of 92 nm.

Referring to FIG. 13, the protection film of the embodiment 1-1 exhibited the reflectance of 0.05% at a wavelength of 550 nm, and the protection film of the embodiment 1-2 exhibited the reflectance of 0.54% at a wavelength of 550 nm.

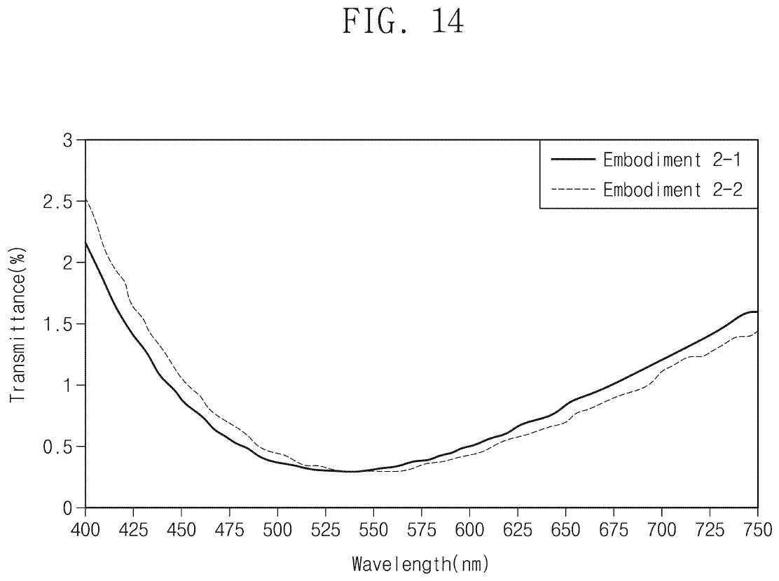

FIG. 14 is a graph showing the simulated wavelength-reflectance characteristics of a protection film of an embodiment 2-1 and a protection film of an embodiment 2-2, when the hard coating layer contains silsesquioxane and acrylic-based copolymer.

In the protection film of the embodiment 2-1, the base portion was PET and had a thickness of 65 m. The hard coating layer included a random-type silsesquioxane compound and a copolymer between TIPA and HEA. The molecular mass of the random-type silsesquioxane compound was between 3,000 and 6000, and the weight ratio between TIPA and HEA was 90:10. The molecular mass of the copolymer between TIPA and an HEA was between 11,000 and 15,000, and the hard coating layer had a thickness of 3 m and a refractive index of 1.72 at a wavelength of 636 nm. In addition, the anti-reflection layer had a single-layered structure including the first anti-reflection portion, which included AlF₃ and had a thickness of 96 nm.

In the protection film of the embodiment 2-2, the base portion was PET and had a thickness of 65 m. The hard coating layer included a random-type silsesquioxane compound and a copolymer between TIPA and HEA. The molecular mass of the random-type silsesquioxane compound was between 3,000 and 6000, and the weight ratio between TIPA and HEA was 90:10. The molecular mass of the copolymer between TIPA and HEA was 11,000 and 15,000, and the hard coating layer had a thickness of 3 m and a refractive index of 1.72 at a wavelength of 636 nm. In addition, the anti-reflection layer had a double-layered structure: the first anti-reflection portion included Si₉Al₂O₁₀ and had a thickness of 9 nm; and the second anti-reflection portion included AlF₃ and had a thickness of 87 nm.

Referring to FIG. 14, the protection film of the embodiment 2-1 and the protection film of the embodiment 2-2 exhibited the low reflectance of 0.3% at a wavelength of 550 nm.

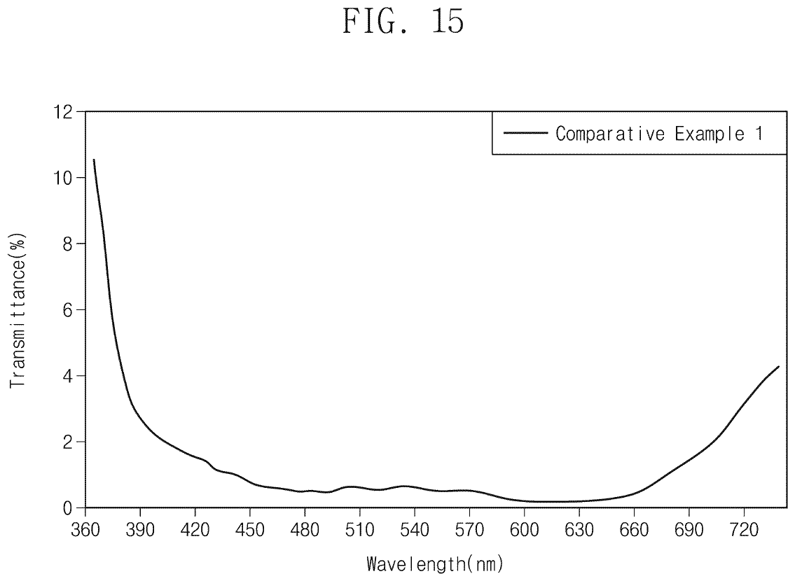

FIG. 15 is a graph showing the reflectance (%) as a function of wavelength (nm), measured from a protection film of a comparative example 1, in which the hard coating layer does not contain silsesquioxane and titanium chelate oligomer or does not contain silsesquioxane and acrylic-based copolymer.

In the protection film of the comparative example 1, the base portion was PET, and the hard coating layer had a refractive index of 1.51 at a wavelength of 636 nm. In addition, the anti-reflection layer had a quintuple-layered structure including first, third, and fifth anti-reflection portions having a low refractive index between 1.3 to 1.5 and second and fourth anti-reflection portions having a high refractive index between 1.6 to 2.3.

Referring to FIG. 15, the protection film of the comparative example 1 exhibited the high reflectance of 0.49% at a wavelength of 550 nm, compared to the protection films of the embodiments 1-1, 1-2, 2-1 and 2-2. Accordingly, if the electronic device includes the protection film according to an embodiment of the inventive concept, the display quality of the electronic device may be improved.

In the electronic device ED described with reference to FIGS. 4 and 5, the protection film PL may include the protection film PL, PL-a, PL-b, or PL-c described with reference to FIGS. 6 to 9.

FIG. 11 is a sectional view illustrating an electronic device ED-b according to an embodiment of the inventive concept and, in particular, briefly illustrates the electronic device described with reference to FIGS. 4 and 5.

Referring to FIG. 11, the electronic device ED-b may include the display module DM including the folding region FA1, the first non-folding region NFA1, and the second non-folding region NFA2, which are spaced apart from each other with the folding region FA1 interposed therebetween; the window module WM disposed on the display module DM; and the protection film PL disposed on the window module WM. Here, the protection film PL may include the base portion BS adjacent to the window module WM; the hard coating layer HC, which is disposed on the base portion BS and contains silsesquioxane and titanium chelate oligomer or contains silsesquioxane and acrylic-based copolymer; and the anti-reflection layer AR, which is disposed on the hard coating layer HC and includes the first anti-reflection portion AR-1 that is adjacent to the hard coating layer HC and has a first refractive index lower than a refractive index of the hard coating layer HC.

In FIG. 11, the anti-reflection layer AR is illustrated to have a single-layered structure, but the inventive concept is not limited to this example; for example, the anti-reflection layer AR may be provided to have a single- or multi-layered structure. For example, the anti-reflection layer AR may be provided to have a single-, double- or triple-layered structure.

In an embodiment, the protection film PL may be included in the electronic device ED-b, and in this case, the durability of the folding region FA1 may be increased. In detail, since the hard coating layer HC has a high refractive index, it may be possible to reduce the number of the layers constituting the anti-reflection layer AR. Even when the anti-reflection layer AR has a single-, double- or triple-layered structure, the anti-reflection layer AR may exhibit excellent optical property (e.g., a low reflectance of 1% or lower at a wavelength of 550 nm) and may have a small thickness (e.g., W_{AR} of FIG. 6) in the third direction DR3. Thus, it may be possible to reduce a compressive stress exerted on the folding region FA1 during the folding operation of the electronic device ED-b and to prevent or suppress a crack issue in the folding region FA1.

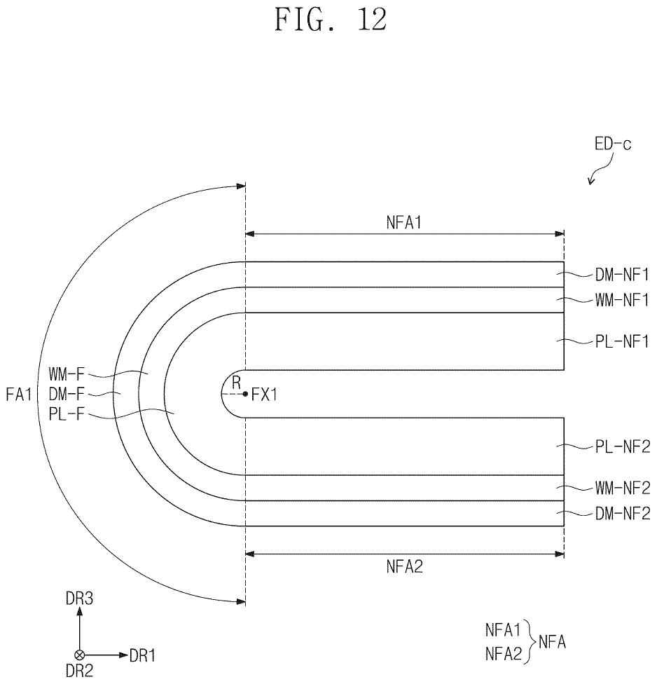

FIG. 12 is an enlarged sectional view illustrating a portion of an electronic device according to an embodiment. FIG. 12 briefly illustrates the electronic device described with reference to FIGS. 4 and 5 and, in particular, illustrates an electronic device ED-c in-folded along the folding region FA1. The device ED-c may include non-folding region NFA that includes a first non-folding region NFA1 and a second non-folding region NFA2 spaced apart from each other with the folding region FA located therebetween. In the first non-folding region NFA1 a first non-folding region display module DM-NF1 may be located, a first non-folding region window module WM-NF1 may be disposed on first non-folding region display module DM-NF1 and the first non-folding region protecting film PL-NF1 may be disposed on first non-folding region window module WM-NF1. Similarly in the second non-folding region NFA2, a second non-folding region display module DM-NF2 may be located, a second non-folding region window module WM-NF2 may be disposed on the second non-folding region display module DM-NF2 and the second non-folding region protecting film PL-NF2 may be disposed on the second non-folding region window module WM-NF2. In the folding region FA1 a folding region display module DM-F may be located adjacent to the first non-folding region display module DM-NF1 and the second non-folding region display module DM-NF2. A folding region window module WM-f may be disposed on the folding region display module DM-F and the folding region protecting film PL-F may be disposed on the folding region window module WM-F.

Referring to FIG. 12, a compressive stress may occur at the folding region FA1 and along the first folding axis FX1. A folding-region protecting film PL-F may be provided in a thin structure that includes a hard coating layer (e.g., HC of FIG. 11) having a high refractive index and an anti-reflection layer (e.g., AR of FIG. 11) including a stack of one, two or three anti-reflection portions. For example, the thickness of the anti-reflection layer AR of FIG. 11 may range from 80 nm to 350 nm. Thus, since the folding-region protecting film PL-F has a small thickness, a compressive stress exerted on the folding region FA1 may be reduced. Since the folding stress is reduced, it may be possible to prevent a crack issue from occurring when the in-folding operation or the out-folding operation is repeated, and this improves the durability of the folding region FA1.

In the present specification, the radius R of the curvature of the folding region FA1 may mean a radius of a circle including a curve formed by an inner section of the folding region FA1, in a state folded along the first folding axis FX1.

In an embodiment, the curvature radius R of the folding region FA1 may range from 1.4 R to 2.0 R. The electronic device ED-c may exhibit excellent folding properties while maintaining the curvature radius to a small range of 1.4 R to 2.0 R.

Referring to FIG. 12, the folding-region protecting film PL-F may have a small thickness, and thus the curvature radius R of the folding region FA1 may be reduced. In an embodiment, the electronic device ED-c may have a curvature radius ranging from 1.4 R to 2.0 R. The electronic device ED-c may have improved durability characteristics, without a crack issue, when the curvature radius is within a small range of 1.4 R to 2.0 R.

FIG. 12 illustrates the electronic device ED-c in the in-folding state, but the inventive concept is not limited to this example. For example, even when the electronic device ED-c is in an out-folding state, the durability of the folding region FA1 may be improved by the folding-region protecting film PL-F according to an embodiment of the inventive concept.

According to an embodiment of the inventive concept, a protection film may include a high refractive index hard coating layer containing silsesquioxane and titanium chelate oligomer or containing silsesquioxane and acrylic-based copolymer, and in this case, it may be possible to reduce a thickness of an anti-reflection layer. Thus, if the protection film is used in the electronic device, the durability of the electronic device may be improved.

According to an embodiment of the inventive concept, an electronic device may include a hard coating layer with a high refractive index, and in this case, it may be possible to reduce a thickness of an anti-reflection layer and to reduce a compressive stress exerted on a folding region during a folding operation. Due to the reduction of the folding stress, a crack issue in the folding region may be suppressed. In addition, the electronic device according to an embodiment of the inventive concept may exhibit a reduced reflectance property. As a result, it may be possible to improve both the durability and the display quality of folding operation.

The foregoing description has been provided with reference to embodiments of the inventive concept. However, those skilled in the art or having ordinary knowledge in the relevant technical field will understand that various modifications and alterations can be made without departing from the spirit and scope of the inventive concept as defined in the claims described below.

Accordingly, the technical scope of the inventive concept should not be limited to the specific embodiments described in the detailed description of the specification, but rather should be defined by the claims.

1. A protection film, comprising:
a base portion;
a hard coating layer disposed on the base portion, the hard coating layer containing silsesquioxane and a titanium chelate oligomer or containing silsesquioxane and an acrylic-based copolymer; and
an anti-reflection layer disposed on the hard coating layer, the anti-reflection layer comprising a first anti-reflection portion, which is disposed adjacent to the hard coating layer to have a first refractive index lower than a refractive index of the hard coating layer.

2. The protection film of claim 1, wherein the anti-reflection layer has a single-layered structure having only the first anti-reflection portion or a stacking structure having two or three layers, in addition to the first anti-reflection portion.

3. The protection film of claim 1, wherein the refractive index of the hard coating layer ranges from 1.35 to 1.5 at a wavelength of 550 nm or ranges 1.6 from 2.0 at a wavelength of 550 nm.

4. The protection film of claim 3, wherein the hard coating layer has the refractive index ranging from 1.6 to 1.75 and includes the silsesquioxane and the titanium chelate oligomer, or has the refractive index ranging from 1.65 to 1.9 and includes the silsesquioxane and the acrylic-based copolymer.

5. The protection film of claim 1, wherein the titanium chelate oligomer is titanium alkoxide oligomer ([Ti(ORₐ)₄]ₙ₁), titanium β-diketone oligomer ([Ti(R_{b}COCH₂COR)₄]ₙ₂), or titanium carboxylate oligomer ([Ti(OOCR_{d})₄]ₙ₃),
each of Rₐ, R_{b}, R_{c}, and R_{d} is independently hydrogen, deuterium, a substituted or unsubstituted C₁-C₂₀ alkyl group, a substituted or unsubstituted C₆-C₃₀ aryl group, or a substituted or unsubstituted C₂-C₃₀ heteroaryl group, and
each of n1 to n3 is independently an integer greater than or equal to 4 and less than or equal to 8.

6. The protection film of claim 1, wherein the hard coating layer includes the silsesquioxane and the titanium chelate oligomer and is directly disposed below the anti-reflection layer.

7. The protection film of claim 1, wherein the hard coating layer including the silsesquioxane and the titanium chelate oligomer comprises:
a lower layer, which is disposed adjacent to the base portion and includes the silsesquioxane; and
an upper layer, which is disposed adjacent to the anti-reflection layer and includes the titanium chelate oligomer.

8. The protection film of claim 1, wherein a weight ratio between the silsesquioxane and the acrylic-based copolymer ranges from 5:95 to 20:80.

9. The protection film of claim 1, wherein the acrylic-based copolymer is a copolymer of TIPA (2,4,6-Triiodophenyl acrylate) and HEA (2-hydroxyethyl acrylate) or a copolymer of TIPA and EEA (2-(2-ethoxyethoxy)ethyl acrylate).

10. The protection film of claim 9, wherein, in the acrylic-based copolymer, a weight ratio between TIPA and HEA or a weight ratio between TIPA and EEA ranges from 97:3 to 75:25.

11. The protection film of claim 1, wherein a weight-average molecular weight of the acrylic-based copolymer ranges from 10,000 to 30,000.

12. The protection film of claim 1, wherein a thickness of the anti-reflection layer ranges from 80 nm to 350 nm.

13. The protection film of claim 1, wherein the anti-reflection layer comprises at least one of SigAl₂O₁₀, SiO₂, Ti₁₄Nb₃O₃₅, and AlF₃.

14. The protection film of claim 1, wherein the anti-reflection layer further comprises a second anti-reflection portion directly disposed on the first anti-reflection portion, and a thickness of the second anti-reflection portion ranges from 75 nm to 95 nm.

15. The protection film of claim 1, wherein the anti-reflection layer further comprises:
a second anti-reflection portion, which is disposed on the first anti-reflection portion and has a second refractive index higher than the first refractive index, and
a third anti-reflection portion, which is disposed on the second anti-reflection portion and has a third refractive index lower than the second refractive index.

16. The protection film of claim 15, wherein the second refractive index is higher than the refractive index of the hard coating layer.

17. The protection film of claim 1, wherein the protection film has a reflectance of 1% or lower, at a wavelength of 550 nm.

18. An electronic device, comprising:
a display module;
a window module disposed on the display module; and
a protection film disposed on the window module,
wherein the protection film comprises:
a base portion disposed on the window module;
a hard coating layer disposed on the base portion, the hard coating layer containing silsesquioxane and titanium chelate oligomer or containing silsesquioxane and acrylic-based copolymer; and
an anti-reflection layer disposed on the hard coating layer, the anti-reflection layer comprising a first anti-reflection portion, which is disposed adjacent to the hard coating layer to have a first refractive index lower than a refractive index of the hard coating layer.

19. An electronic device, comprising:
a display module including a folding region, a first non-folding region, and a second non-folding region, which are spaced apart from each other with the folding region interposed therebetween;
a window module disposed on the display module; and
a protection film disposed on the window module,
wherein the protection film comprises:
a base portion adjacent to the window module;
a hard coating layer disposed on the base portion, the hard coating layer containing silsesquioxane and titanium chelate oligomer or containing silsesquioxane and acrylic-based copolymer; and
an anti-reflection layer disposed on the hard coating layer, the anti-reflection layer comprising a first anti-reflection portion, which is disposed adjacent to the hard coating layer to have a first refractive index lower than a refractive index of the hard coating layer.

20. The electronic device of claim 24, wherein the folding region has a curvature radius that is greater than or equal to 1.4 R and is smaller than 2.0 R.
